(19) United States
(12) Patent Application Publication
(10) Pub. No.: US 2013/0249626 A1
(43) Pub. Date: Sep. 26, 2013

(54) MULTIPLE POWER MODE AMPLIFIER

(71) Applicants: Naoko Matsunaga, Tokyo (JP); Kenichi Horiguchi, Tokyo (JP); Hiroshi Otsuka, Tokyo (JP); Masatoshi Nakayama, Tokyo (JP); Kazuhiro Iyomasa, Tokyo (JP); Kazuya Yamamoto, Tokyo (JP); Akira Inoue, Tokyo (JP)

(72) Inventors: Naoko Matsunaga, Tokyo (JP); Kenichi Horiguchi, Tokyo (JP); Hiroshi Otsuka, Tokyo (JP); Masatoshi Nakayama, Tokyo (JP); Kazuhiro Iyomasa, Tokyo (JP); Kazuya Yamamoto, Tokyo (JP); Akira Inoue, Tokyo (JP)

(73) Assignee: Mitsubishi Electric Corporation, Tokyo (JP)

(21) Appl. No.: 13/992,317

(22) PCT Filed: Nov. 9, 2011
(86) PCT No.: PCT/JP2011/075862

§ 371 Date: Jun. 7, 2013

(30) Foreign Application Priority Data
Jan. 19, 2011 (JP) 2011-008934

(51) Int. Cl. H03F 1/02

(52) U.S. Cl. CPC H03F 1/0277
USPC 330/51

(57) ABSTRACT

A multiple power mode amplifier includes: N amplifiers connected in series via switches; and a control circuit for controlling the N amplifiers in accordance with the output modes. P amplifiers out of the N amplifiers constitute a driver amplifier, and constitute a negative feedback amplifier including a feedback circuit for negatively feeding back its own output signal to its own input side. N−P amplifiers constitute a final stage amplifier connected in series to the negative feedback amplifier in a disconnectable manner. The control circuit is configured to: in a first output mode, disconnect the final stage amplifier from the negative feedback amplifier, and disable the feedback circuit; and in a second output mode, connect the final stage amplifier in series to the negative feedback amplifier, and enable the feedback circuit.

### TECHNICAL FIELD

The present invention relates to a multiple power mode amplifier for realizing high efficiency characteristics over a wide range of output power.

### BACKGROUND ART

In recent years, mobile communication terminals have been required to be reduced in power consumption in order to downsize a battery. Particularly in mobile phone terminals, in order to reduce the power consumption, transmission power of the terminal is caused to vary depending on a distance between the terminal and a base station and a real-time change in communication state. It is therefore required for an amplifier used in the terminal to be high in efficiency over a wide range of output power.

In order to meet the above-mentioned requirements, a multiple power mode amplifier that is adaptable to a low output power mode and a high output power mode has been widely employed as an amplifier for a mobile communication terminal, and the mainstream technology is to switch among a plurality of output modes (see, for example, Patent Literature 1).

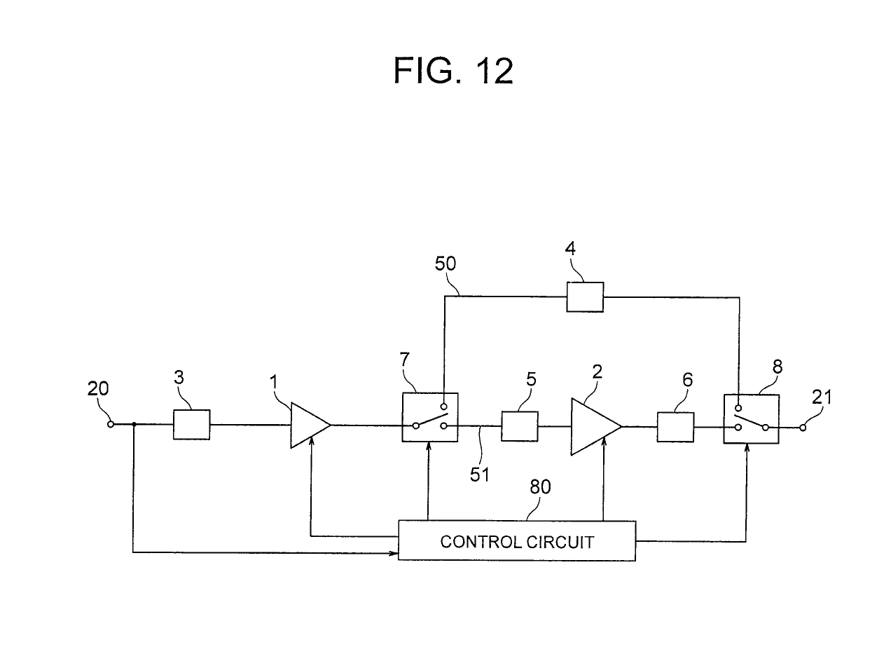

FIG. 12 is a circuit block diagram illustrating a configuration of a conventional multiple power mode amplifier, and illustrates a switching configuration corresponding to each of two output modes for low output power and high output power as disclosed in Patent Literature 1, for example.

In FIG. 12, the multiple power mode amplifier includes a driver amplifier 1, a final stage amplifier 2, first and second matching circuits 3 and 4 interposed between input and output terminals of the driver amplifier 1, third and fourth matching circuits 5 and 6 interposed between input and output terminals of the final stage amplifier 2, switches 7 and 8 for output mode switching, an input terminal 20, an output terminal 21, first and second paths 50 and 51, and a control circuit 80 for controlling the driver amplifier 1, the final stage amplifier 2, and the switches 7 and 8.

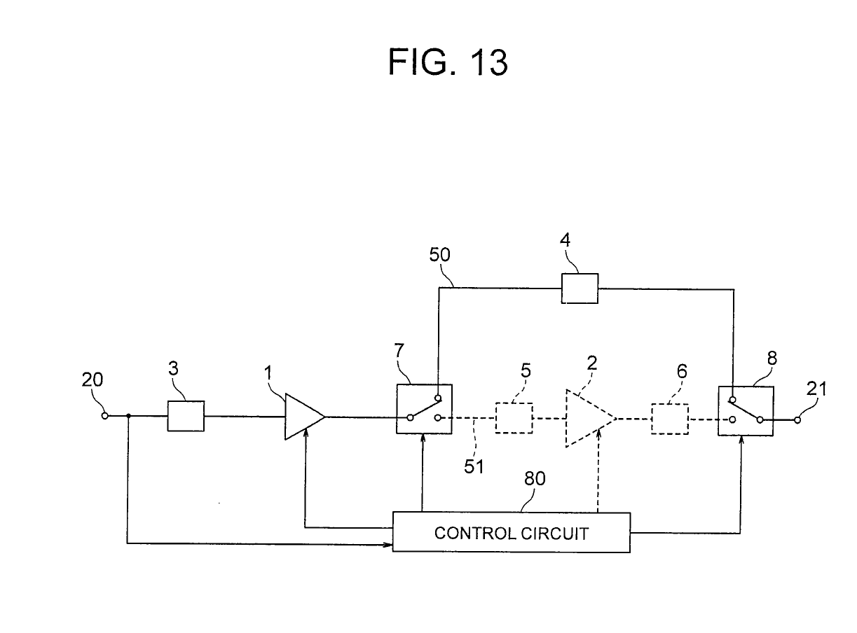

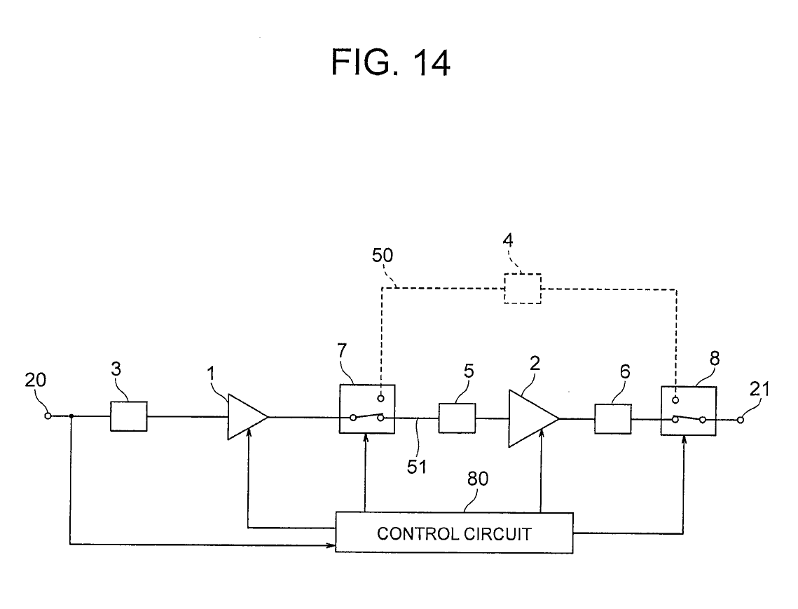

FIGS. 13 and 14 are circuit block diagrams illustrating the configurations in the respective output modes. FIG. 13 illustrates a circuit configuration in a first output mode in which required output power is low. FIG. 14 illustrates a circuit configuration in a second output mode in which required output power is high.

Next, the operation of the conventional multiple power mode amplifier is described with reference to FIGS. 12 to 14.

First, as illustrated in FIG. 13, in the first output mode in which required output power is low, the control circuit 80 generates a first switching control signal for the switches 7 and 8, to thereby switch to the first path 50 that excludes the final stage amplifier 2 (see broken line).

At the same time, the control circuit 80 turns ON the supply of a power supply voltage to the driver amplifier 1, and turns OFF the supply of a power supply voltage to the final stage amplifier 2.

In the case of the first output mode (FIG. 13), an input signal input from the input terminal 20 is input to the driver amplifier 1 via the first matching circuit 3, and the amplified input signal is input to the second matching circuit 4 via the first switch 7 and the first path 50. Subsequently, an output signal from the second matching circuit 4 is output from the output terminal 21 via the first switch 8.

In this case, the input signal from the input terminal 20 is amplified only by the driver amplifier 1, and hence low output power is obtained.

On the other hand, as illustrated in FIG. 14, in the second output mode in which required output power is high, the control circuit 80 generates a second switching control signal for the switches 7 and 8, to thereby switch from the first path 50 (see broken line) to the second path 51 that includes the final stage amplifier 2.

At the same time, the control circuit 80 turns ON the supply of the power supply voltages to both the driver amplifier 1 and the final stage amplifier 2.

In the case of the second output mode (FIG. 14), an input signal input from the input terminal 20 is input to the driver amplifier 1 via the first matching circuit 3, and the amplified input signal is input to the third matching circuit 5 via the first switch 7 and the second path 51. Subsequently, an output signal from the third matching circuit 5 is input to the final stage amplifier 2 and amplified, and an output signal of the final stage amplifier 2 is output from the output terminal 21 via the fourth matching circuit 6 and the first switch 8.

In this case, the input signal from the input terminal 20 is amplified by the driver amplifier 1 and the final stage amplifier 2, and hence high output power is obtained.

In this way, the multiple power mode amplifier switches the amplifier to be operated in accordance with required output power, thus realizing a high efficiency operation over a wide range of output power.

### CITATION LIST

### Patent Literature

[PTL 1] JP 2001-217661 A

### SUMMARY OF INVENTION

### Technical Problem

The conventional multiple power mode amplifier obtains a sufficient and necessary gain by single amplification of the driver amplifier 1 alone in the first output mode in which required output power is low. In the second output mode in which required output power is high, however, the conventional multiple power mode amplifier operates as a two-stage amplifier of the driver amplifier 1 and the final stage amplifier 2. Thus, there has been a problem in that the gain becomes much higher than a necessary gain to deteriorate receive band noise.

A possible measure to suppress the gain in the second output mode is to load an additional attenuator between the stages of the driver amplifier 1 and the final stage amplifier 2 or on the output side of the final stage amplifier 2. However, there has been a problem in that the loaded attenuator deteriorates the efficiency.

The present invention has been made in order to solve the above-mentioned problems, and it is an object thereof to provide a multiple power mode amplifier for suppressing deterioration of receive band noise while realizing a desired gain.

### Solution to Problems

According to the present invention, there is provided a multiple power mode amplifier having a plurality of output modes with different levels of output power, including: N amplifiers, where N is a natural number of 2 or more, which are connected in series via switching means; and a control circuit for controlling switching of a connection state and an ON/OFF state of the N amplifiers in accordance with the plurality of output modes, in which P amplifiers, where P is a natural number of 1 or more and P≦N, out of the N amplifiers constitute a driver amplifier, and constitute a negative feedback amplifier including a feedback circuit for negatively feeding back its own output signal to an input side of the negative feedback amplifier, in which N−P amplifiers out of the N amplifiers constitute a final stage amplifier that is connected in series to the negative feedback amplifier in a disconnectable manner, and in which the control circuit is configured to: in a first output mode in which required output power is relatively low, disconnect the final stage amplifier from the negative feedback amplifier, and disable the feedback circuit connected in parallel to the driver amplifier; and in a second output mode in which required output power is relatively high, connect the final stage amplifier in series to the negative feedback amplifier, and enable the feedback circuit.

### Advantageous Effects of Invention

According to the present invention, the negative feedback circuit for suppressing the gain of the driver amplifier only in the second output mode is provided. Thus, the deterioration of receive band noise can be suppressed while a desired gain is realized.

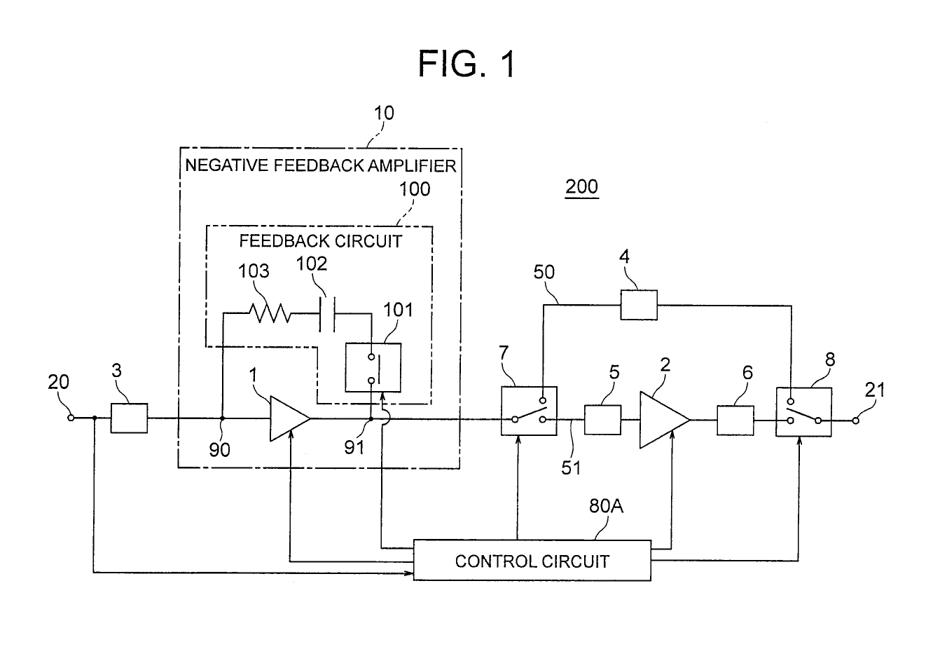

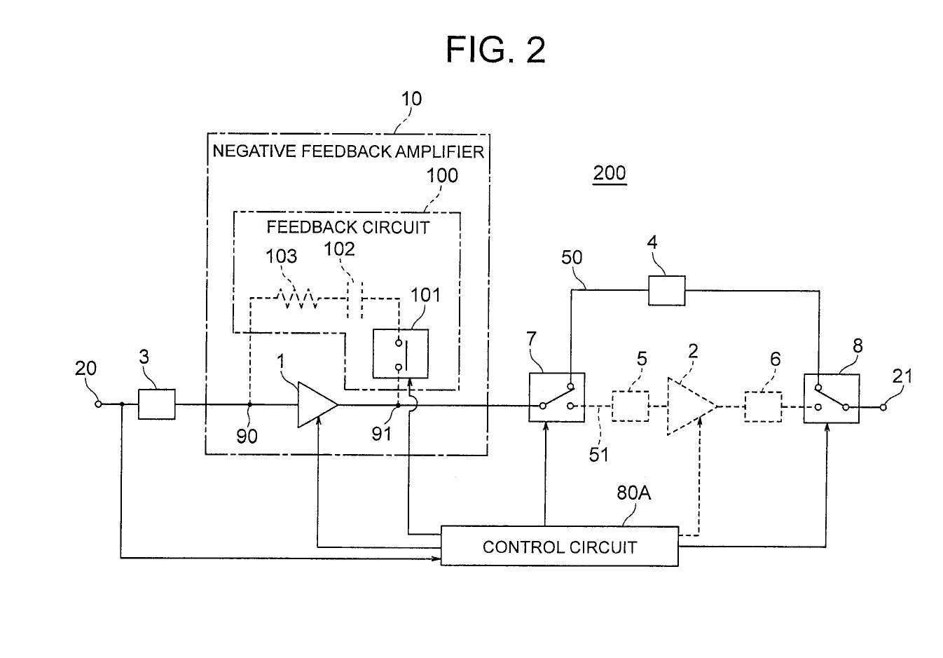

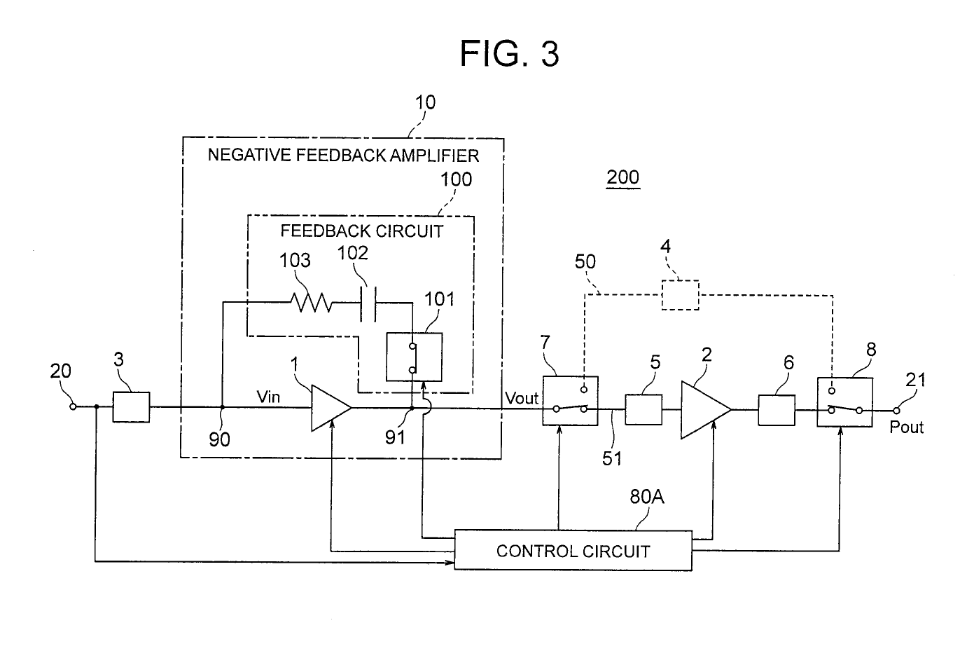

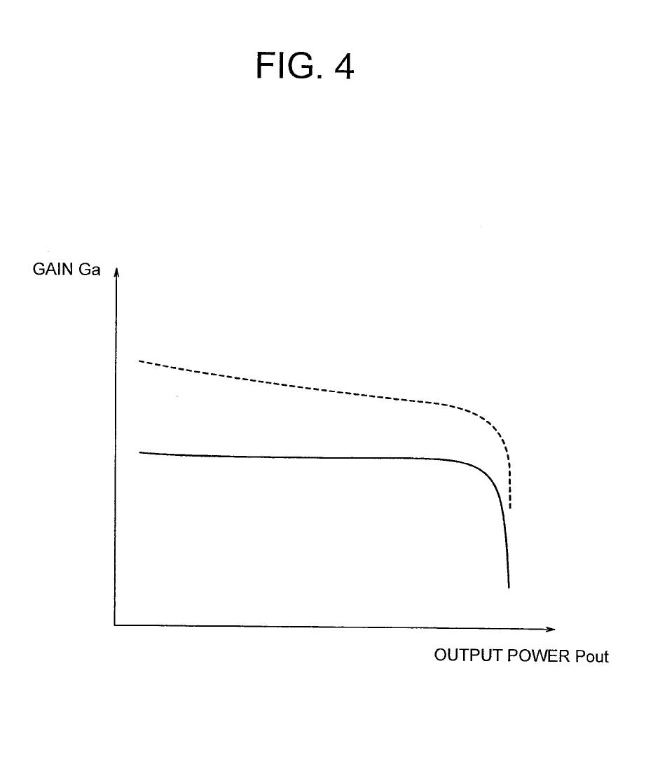

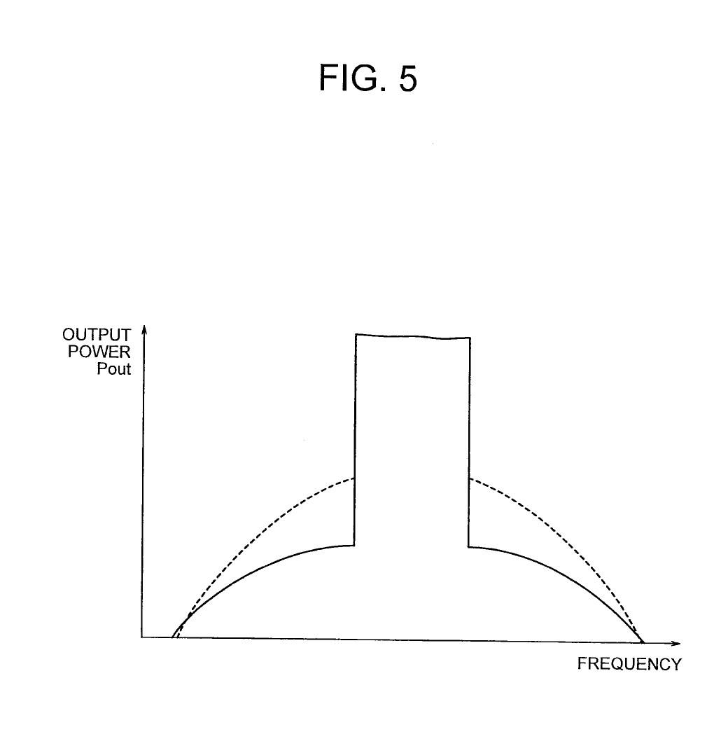

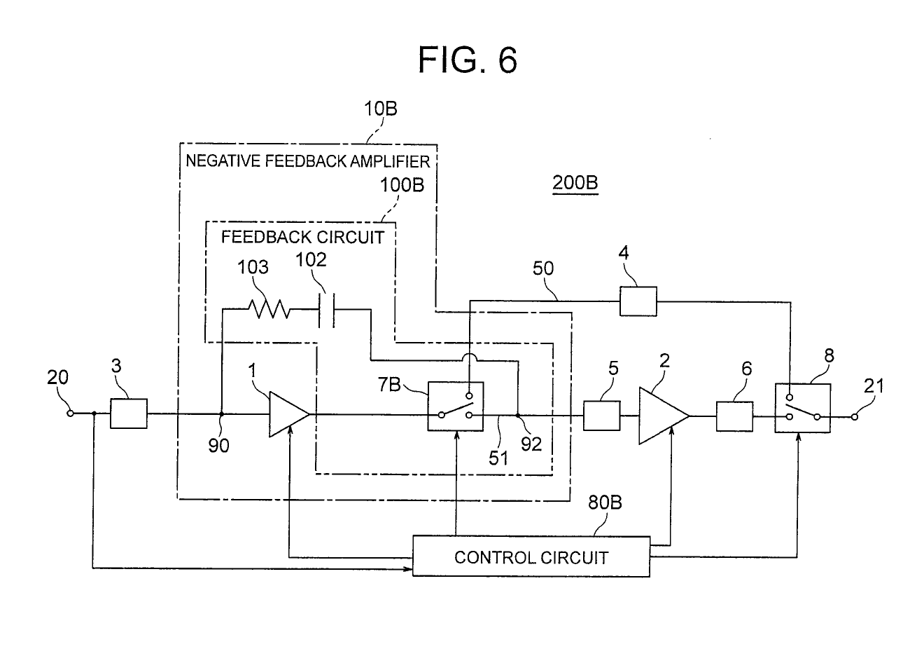

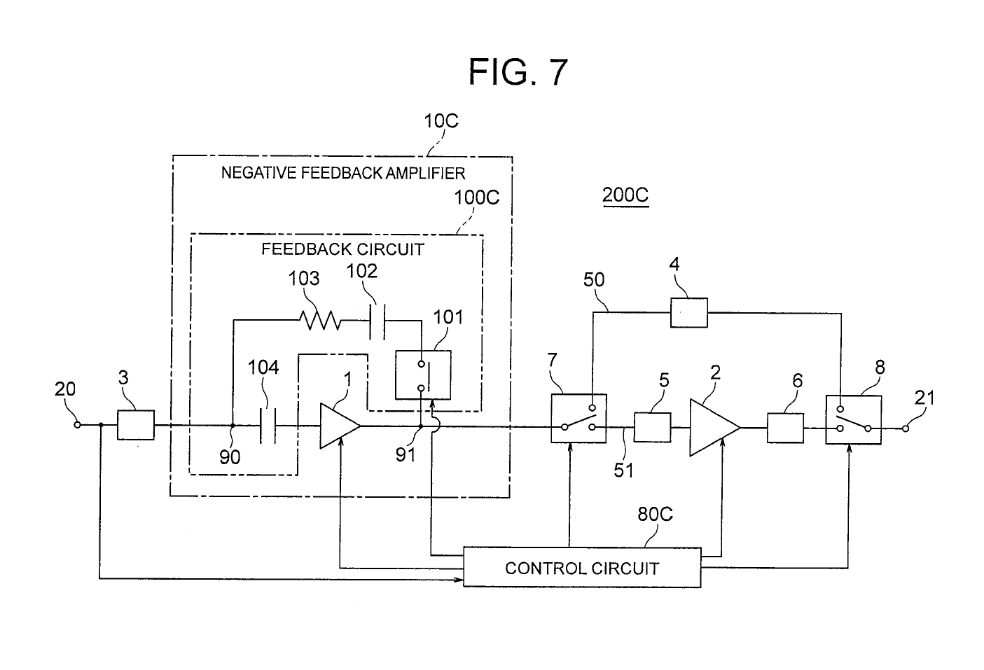

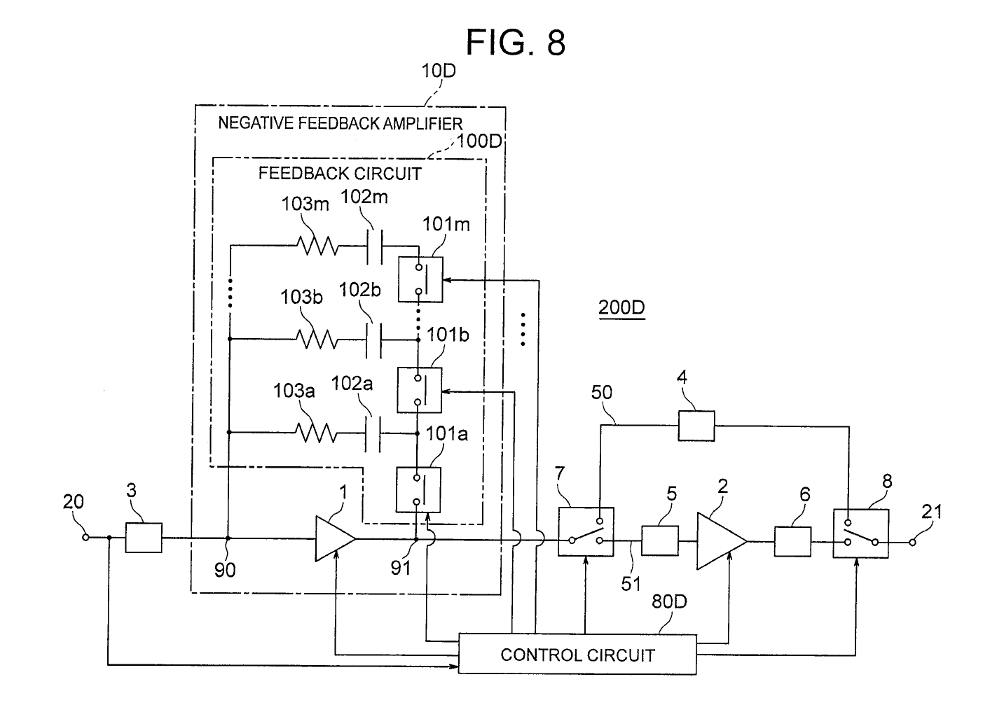

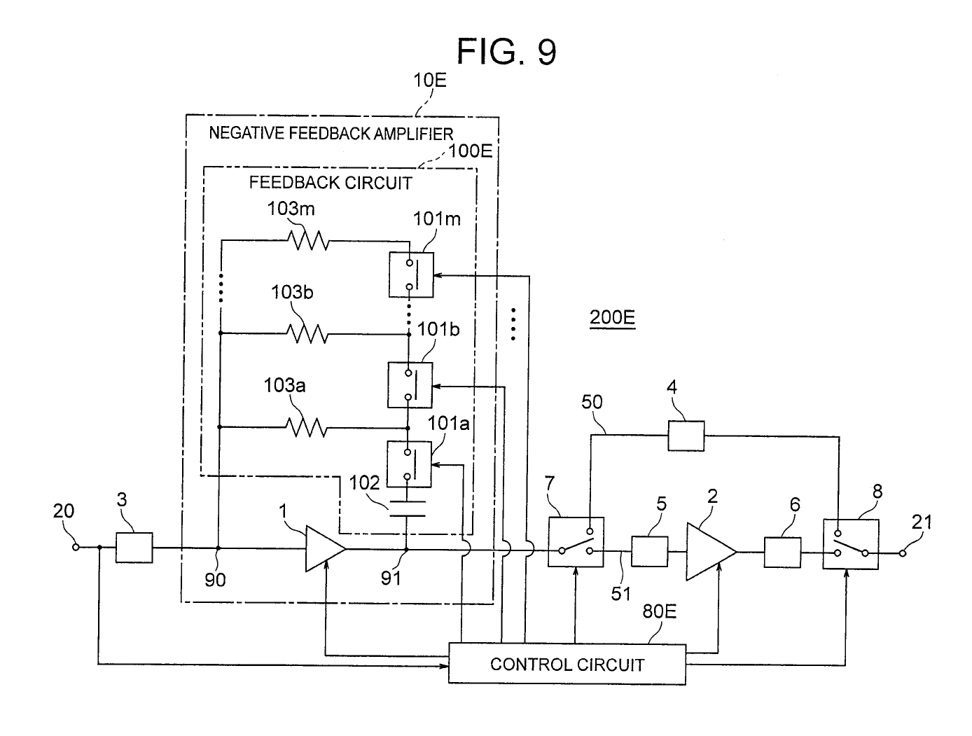

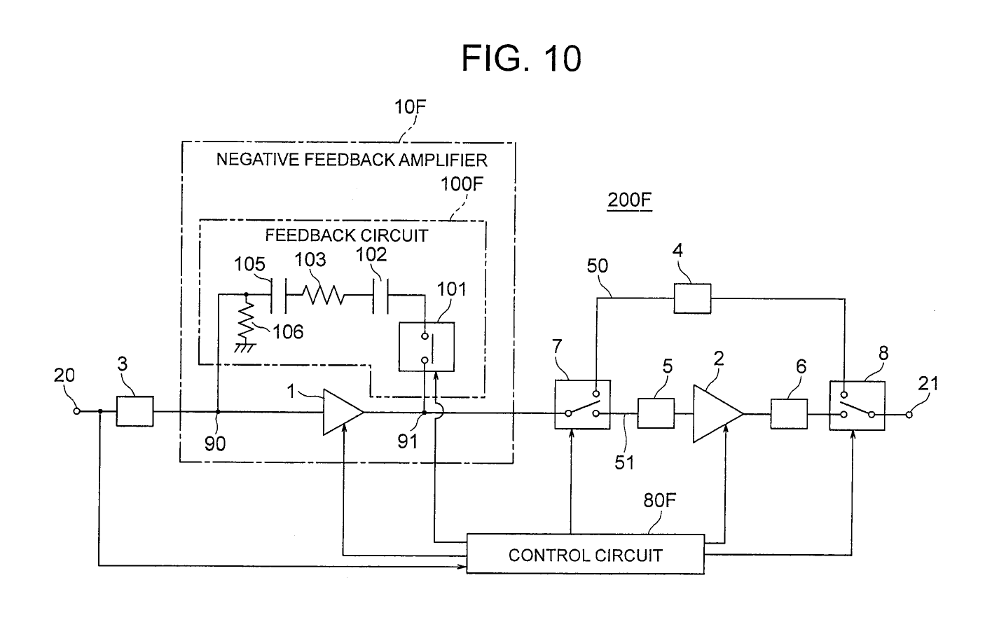

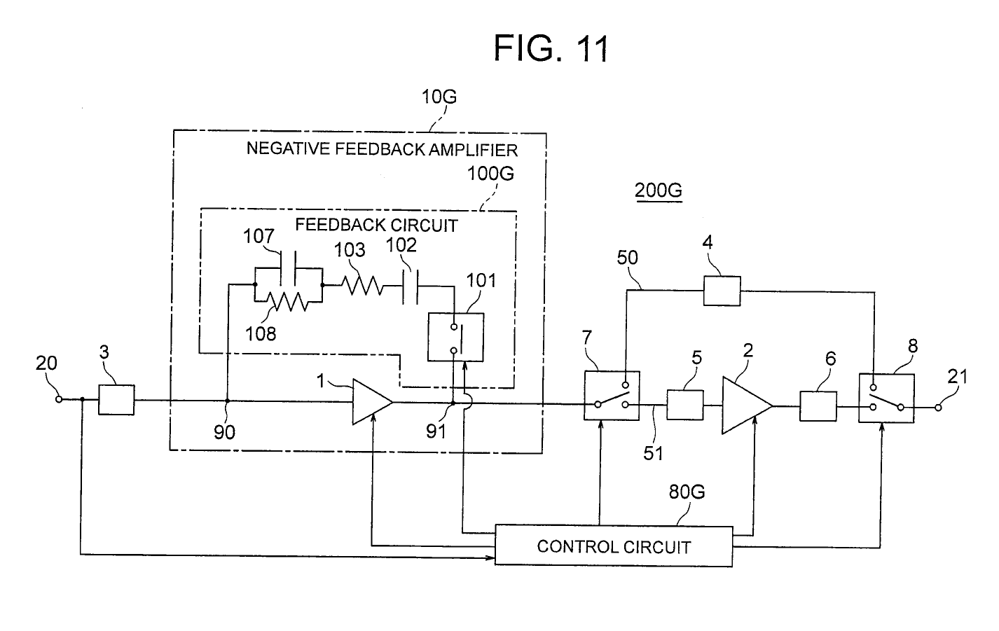

### BRIEF DESCRIPTION OF DRAWINGS

[FIG. 1] FIG. 1 is a circuit block diagram illustrating a configuration of a multiple power mode amplifier according to a first embodiment of the present invention (Embodiment 1).

[FIG. 2] FIG. 2 is a circuit block diagram illustrating a configuration in a first output mode of the multiple power mode amplifier according to the first embodiment of the present invention (Embodiment 1).

[FIG. 3] FIG. 3 is a circuit block diagram illustrating a configuration in a second output mode of the multiple power mode amplifier according to the first embodiment of the present invention (Embodiment 1).

[FIG. 4] FIG. 4 is an explanatory diagram showing output/gain characteristics of the multiple power mode amplifier according to the first embodiment of the present invention (Embodiment 1).

[FIG. 5] FIG. 5 is an explanatory diagram showing frequency/output characteristics of the multiple power mode amplifier according to the first embodiment of the present invention (Embodiment 1).

[FIG. 6] FIG. 6 is a circuit block diagram illustrating a configuration of a multiple power mode amplifier according to a second embodiment of the present invention (Embodiment 2).

[FIG. 7] FIG. 7 is a circuit block diagram illustrating a configuration of a multiple power mode amplifier according to a third embodiment of the present invention (Embodiment 3).

[FIG. 8] FIG. 8 is a circuit block diagram illustrating a configuration of a multiple power mode amplifier according to a fourth embodiment of the present invention (Embodiment 4).

[FIG. 9] FIG. 9 is a circuit block diagram illustrating a configuration of a multiple power mode amplifier according to a fifth embodiment of the present invention (Embodiment 5).

[FIG. 10] FIG. 10 is a circuit block diagram illustrating a configuration of a multiple power mode amplifier according to a sixth embodiment of the present invention (Embodiment 6).

[FIG. 11] FIG. 11 is a circuit block diagram illustrating another configuration of the multiple power mode amplifier according to the sixth embodiment of the present invention (Embodiment 6).

[FIG. 12] FIG. 12 is a circuit block diagram illustrating a configuration of a conventional multiple power mode amplifier.

[FIG. 13] FIG. 13 is a circuit block diagram illustrating a configuration in a first output mode of the conventional multiple power mode amplifier.

[FIG. 14] FIG. 14 is a circuit block diagram illustrating a configuration in a second output mode of the conventional multiple power mode amplifier.

### DESCRIPTION OF EMBODIMENTS

### Embodiment 1

Referring to the accompanying drawings, a first embodiment of the present invention is described in detail below.

FIG. 1 is a circuit block diagram illustrating a configuration of a multiple power mode amplifier 200 according to the first embodiment of the present invention.

In FIG. 1, the multiple power mode amplifier 200 includes, similarly to the above-mentioned configuration, a driver amplifier 1, a final stage amplifier 2, first to fourth matching circuits 3 to 6, first switches 7 and 8, an input terminal 20, an output terminal 21, first and second paths 50 and 51, and a control circuit 80A.

The multiple power mode amplifier 200 further includes, in addition to the above-mentioned configuration, a second switch 101 connected to an output terminal 91 of the driver amplifier 1, a capacitive element 102 connected to the second switch 101, and a resistive element 103 interposed between the capacitive element 102 and an input terminal 90 of the driver amplifier 1.

The second switch 101, the capacitive element 102, and the resistive element 103 constitute a feedback circuit 100 of the driver amplifier 1.

As a result, the driver amplifier 1 is provided with negative feedback by the feedback circuit 100, and constitutes a negative feedback amplifier 10 together with the feedback circuit 100 (the second switch 101, the capacitive element 102, and the resistive element 103).

The multiple power mode amplifier 200 of FIG. 1 is different from the conventional multiple power mode amplifier (FIG. 12) in that the feedback circuit 100 (the second switch 101, the capacitive element 102, and the resistive element 103) is additionally provided between the input terminal 90 and the output terminal 91 of the driver amplifier 1 in parallel to the driver amplifier 1.

The control circuit 80A automatically determines an output mode in accordance with the current level of an input signal input via the input terminal 20, and controls the second switch 101 in the feedback circuit 100 as well as the driver amplifier 1, the final stage amplifier 2, and the first switches 7 and 8.

For example, when the current level of the input signal is higher than a reference value, the control circuit 80A performs a control operation for automatically switching to a second output mode.

In a first output mode in which required output power is low, the control circuit 80A generates a first switching control signal to turn OFF (open) the second switch 101, to thereby maintain the gain of the driver amplifier 1.

In the second output mode in which required output power is high, on the other hand, the control circuit 80A generates a second switching control signal to turn ON (electrically connect) the second switch 101, to thereby enable the feedback circuit 100 to suppress the gain of the driver amplifier 1 by negative feedback.

In other words, the feedback circuit 100 is controlled so that the gain of the driver amplifier 1 is maintained in the first output mode and that the gain of the driver amplifier 1 is suppressed in the second output mode. Thus, the multiple power mode amplifier 200 can obtain a desired gain corresponding to the output mode. In addition, the effect of negative feedback can reduce a non-linear distortion in the second output mode.

Next, the specific operation according to the first embodiment of the present invention illustrated in FIG. 1 is described with reference to FIGS. 2 and 3.

FIG. 2 is a circuit block diagram illustrating the configuration in the first output mode. FIG. 3 is a circuit block diagram illustrating the configuration in the second output mode.

First, as illustrated in FIG. 2, in the first output mode in which required output power is low, the control circuit 80A generates the first switching control signal for the first and second switches 7, 8, and 101 so that the path is switched by the first switches 7 and 8 to the first path 50 that excludes the final stage amplifier 2 (see broken line), and turns OFF the second switch 101 to disable the feedback circuit 100 (see broken line).

At the same time, the control circuit 80A turns ON the supply of a power supply voltage to the driver amplifier 1, and turns OFF the supply of a power supply voltage to the final stage amplifier 2.

In the case of the first output mode (FIG. 2), the operation of the multiple power mode amplifier 200 is similar to the above-mentioned operation (FIG. 13), and the multiple power mode amplifier 200 functions as a single-stage amplifier while maintaining the gain of the driver amplifier 1.

As illustrated in FIG. 3, in the second output mode in which required output power is high, on the other hand, the control circuit 80A generates the second switching control signal for the first and second switches 7, 8, and 101 so that the path is switched by the first switches 7 and 8 to the second path 51 that includes the final stage amplifier 2, and turns ON the second switch 101 to enable the feedback circuit 100.

At the same time, the control circuit 80A turns ON the supply of the power supply voltages to both the driver amplifier 1 and the final stage amplifier 2.

In the case of the second output mode (FIG. 3), an input signal input from the input terminal 20 to the driver amplifier 1 via the first matching circuit 3 is amplified by the driver amplifier 1, and is thereafter negatively fed back to the input terminal 90 of the driver amplifier 1 from the output terminal 91 via the feedback circuit 100 (the second switch 101, the capacitive element 102, and the resistive element 103).

In this case, a voltage Vout of the output signal from the negative feedback amplifier 10 is expressed by Expression (1) below by using a voltage Vin of the input signal to the negative feedback amplifier 10, a gain Gdrv of the driver amplifier 1, a feedback amount β(<1) of the feedback circuit 100, and a distortion D generated in the driver amplifier 1.

Vout=(Vin/β)+(D/Gdrv·β) (1)

Note that, in Expression (1), Gdrv·β>>1 is established, and hence the value of the second term (right side) can be neglected.

Therefore, as is apparent from the first term (left side) of Expression (1), when negative feedback with the feedback amount β is provided to the driver amplifier 1 having the gain Gdrv, a gain Gdrv_fb of the negative feedback amplifier 10 is simply expressed by Expression (2) below.

Gdrv_{—}fb=1/β (2)

As is apparent from Expression (2), it is understood that the gain Gdrv_fb of the negative feedback amplifier 10 is reduced from the gain Gdrv of the driver amplifier 1 by 1/β.

As is also apparent from Expression (1), it is understood that the distortion D generated in the driver amplifier 1 is reduced by the loop gain Gdrv·β because of the negative feedback.

Subsequently, the output signal of the negative feedback amplifier 10 is input to the final stage amplifier 2 via the first switch 7, the second path 51, and the third matching circuit 5 to be further amplified by the final stage amplifier 2, and is thereafter output from the output terminal 21 via the fourth matching circuit 6 and the first switch 8.

As a result, the input signal input from the input terminal 20 is amplified by both the driver amplifier 1 and the final stage amplifier 2, and is output from the output terminal 21 as high output power having a suppressed gain.

In general, in the second output mode, non-linear characteristics of two amplifiers, namely the driver amplifier 1 and the final stage amplifier 2, are superimposed on each other to generate a larger distortion than in the first output mode. However, the non-linear distortion can be reduced by the negative feedback of the feedback circuit 100 in the driver amplifier 1.

FIGS. 4 and 5 are explanatory diagrams showing operating characteristics in the second output mode of the multiple power mode amplifier 200 according to the first embodiment of the present invention. FIG. 4 shows output power/gain characteristics, and FIG. 5 shows frequency/output characteristics.

In FIGS. 4 and 5, the respective characteristics are shown in comparison with conventional characteristics (broken lines). In FIG. 4, the horizontal axis represents output power Pout, and the vertical axis represents a gain Ga. In FIG. 5, the horizontal axis represents an output frequency, and the vertical axis represents the output power Pout.

In the second output mode, the conventional characteristics (broken lines) show that the gain Ga is excessively high with respect to the overall output power Pout (see FIG. 4) and the distortion of the output power Pout with respect to the frequency is also large (see FIG. 5).

On the other hand, the first embodiment of the present invention (solid lines) shows that the gain Ga is uniformly suppressed (see FIG. 4) and the distortion of the output power Pout with respect to the frequency is also small (see FIG. 5).

Although one driver amplifier 1 and one final stage amplifier 2 are used herein, an arbitrary number of the driver amplifiers 1 and an arbitrary number of the final stage amplifiers 2 (P driver amplifiers 1 connected in series and N−P final stage amplifiers 2 connected in series) may be used depending on a required gain.

Although the multiple power mode amplifier 200 having two output modes has been exemplified, the number of the output modes is not limited to two. It should be understood that the present invention is applicable also to a multiple power mode amplifier having any plurality of output modes.

As described above, the multiple power mode amplifier according to the first embodiment (FIGS. 1 to 5) of the present invention is the multiple power mode amplifier 200 having a plurality of output modes with different levels of output power, and includes N amplifiers (the driver amplifier 1 and the final stage amplifier 2) (in FIG. 1, N=2), which are connected in series via switching means, and the control circuit 80A for controlling switching of a connection state and an ON/OFF state of the N amplifiers in accordance with the plurality of output modes.

P amplifiers (in FIG. 1, P=1) out of the N amplifiers constitute the driver amplifier 1, and constitute the negative feedback amplifier 10 including the feedback circuit 100 for negatively feeding back its own output signal to the input side of the negative feedback amplifier 10.

N−P amplifiers (in FIG. 1, N−P=1) out of the N amplifiers constitute the final stage amplifier 2 that is connected in series to the negative feedback amplifier 10 in a disconnectable manner.

The control circuit 80A is configured to, in the first output mode in which required output power is relatively low, disconnect the final stage amplifier 2 from the negative feedback amplifier 10, and disable the feedback circuit 100 connected in parallel to the driver amplifier. The control circuit 80A is configured to, in the second output mode in which required output power is relatively high, connect the final stage amplifier 2 in series to the negative feedback amplifier 10, and enable the feedback circuit 100.

Specifically, the first switch 7 (first switching means) is interposed between the negative feedback amplifier 10 and the final stage amplifier 2, the first switch 8 (first switching means) is interposed on the output side of the final stage amplifier 2, and the second switch 101 (second switching means) is interposed between the output side of the driver amplifier 1 and the feedback circuit 100.

The feedback circuit 100 includes at least one of the resistive element 103 and the capacitive element 102, and includes, for example, a series-connected circuit of the resistive element 103 and the capacitive element 102 as illustrated in FIG. 1.

The control circuit 80A is configured to, in the first output mode, switch the first switches 7 and 8 to short-circuit the final stage amplifier 2, and turn OFF the second switch 101 to disable the feedback circuit 100. The control circuit 80A is configured to, in the second output mode, switch the first switches 7 and 8 to connect the final stage amplifier 2 in series to the negative feedback amplifier 10, and turn ON the second switch 101 to enable the feedback circuit 100.

The negative feedback amplifier 10 is configured to, in the second output mode, amplify an input signal by an amplification factor (a gain) lower than an amplification factor (a gain) in the first output mode.

The final stage amplifier 2 is configured to further amplify an output signal from the negative feedback amplifier 10 only in the second output mode.

In this way, in the first output mode, the feedback circuit 100 is disabled to maintain the gain of the driver amplifier 1, and, in the second output mode, the feedback circuit 100 is enabled to suppress the gain of the driver amplifier 1. Thus, an excessive gain can be prevented in the second output mode.

Therefore, desired gains can be obtained in different output modes, and the deterioration of receive band noise can be suppressed.

Another effect of reducing the distortion even in the second output mode having high non-linear characteristics can be obtained.

### Embodiment 2

In the above-mentioned first embodiment (FIG. 1), the second switch 101 is provided in the feedback circuit 100. Alternatively, however, as illustrated in FIG. 6, the function of the second switch 101 may be shared by a first switch 7B to omit the second switch 101.

FIG. 6 is a circuit block diagram illustrating a configuration of a multiple power mode amplifier 200B according to a second embodiment of the present invention. The same components as described above (see FIG. 1) are denoted by the same reference symbols or suffixed with “B”, and detailed description thereof is omitted.

In FIG. 6, one terminal of the capacitive element 102 in a feedback circuit 100B is connected to an output terminal 92 of the first switch 7B.

The multiple power mode amplifier 200B of FIG. 6 is different from the above-mentioned multiple power mode amplifier 200 (FIG. 1) in that the second switch 101 is removed and the first switch 7B is used instead to perform a switching operation between the first path 50 and the second path 51 and an ON/OFF switching operation of the feedback circuit 100B.

In this case, the first switch 7B constitutes the feedback circuit 100B together with the capacitive element 102 and the resistive element 103, and constitutes a negative feedback amplifier 10B together with the driver amplifier 1. Thus, the first switch 7B is used both for the switching operation of the signal paths for mode changing and for the ON/OFF switching operation of the feedback circuit 100B.

In this way, as compared to the above-mentioned first embodiment, it is not necessary to load the second switch in the feedback circuit 100B, and hence downsizing can be achieved.

Next, description is given of the specific operation according to the second embodiment of the present invention illustrated in FIG. 6.

First, in the first output mode, a control circuit 80B uses a first switching control signal to connect the first switches 7B and 8 to the first path 50 side, and turn ON only the driver amplifier 1.

At this time, the capacitive element 102 is disconnected from the first switch 7B, and hence the feedback circuit 100B is disabled, and the operation similar to the above-mentioned operation (FIG. 2) is performed.

On the other hand, in the second output mode, a control circuit 80B uses a second switching control signal to connect the first switches 7B and 8 to the second path 51 side, and turn ON both the driver amplifier 1 and the final stage amplifier 2.

At this time, the capacitive element 102 is connected to the first switch 7B, and hence the feedback circuit 100B is enabled, and the operation similar to the above-mentioned operation (FIG. 3) is performed.

As described above, according to the second embodiment (FIG. 6) of the present invention, the function of the second switch 101 is shared by single switching means (first switch 7B), and the first switch 7B is used both for switching the paths of the input signal and for turning ON/OFF the feedback circuit 100B. Thus, the gain of the driver amplifier 1 can be maintained in the first output mode, and the gain of the driver amplifier 1 can be suppressed and the non-linear distortion can be reduced in the second output mode.

It is not necessary to load the second switch in the feedback circuit 100B, and hence further downsizing can be realized as compared to the above-mentioned first embodiment.

### Embodiment 3

Although not specifically described in the above-mentioned first and second embodiments (FIGS. 1 and 6), as illustrated in FIG. 7, a DC blocking capacitive element 104 may be interposed on the input terminal 90 side of the driver amplifier 1.

FIG. 7 is a circuit block diagram illustrating a configuration of a multiple power mode amplifier 200C according to a third embodiment of the present invention. The same components as described above (see FIG. 1) are denoted by the same reference symbols or suffixed with “C”, and detailed description thereof is omitted. In this embodiment, the case where the DC blocking capacitive element 104 is added to the circuit configuration of FIG. 1 is shown. Alternatively, however, the DC blocking capacitive element 104 may be added to the circuit configuration of FIG. 6.

In FIG. 7, the DC blocking capacitive element 104 is interposed on the input terminal 90 side of the driver amplifier 1, and the DC blocking capacitive element 104 constitutes a negative feedback amplifier 10C together with the second switch 101, the capacitive element 102, and the resistive element 103.

The multiple power mode amplifier 200C of FIG. 7 is different from the above-mentioned multiple power mode amplifier 200 (FIG. 1) in that the DC blocking capacitive element 104 is loaded on the input side of the driver amplifier 1 to constitute the negative feedback amplifier 10C (feedback loop) including the DC blocking capacitive element 104.

Specifically, a feedback circuit 100C includes, in addition to the second switch 101, the capacitive element 102, and the resistive element 103, the DC blocking capacitive element 104 that is connected in series to the input side of the driver amplifier 1.

In this way, as compared to the above-mentioned first embodiment, power at low frequency input to the driver amplifier 1 is decreased and the loop gain is decreased due to the effect of the DC blocking capacitive element 104, and hence the oscillation of the driver amplifier 1 at low frequency can be suppressed.

Next, description is given of the specific operation according to the third embodiment of the present invention illustrated in FIG. 7.

First, in the first output mode, similarly to the above (FIG. 2), the first switches 7 and 8 are switched to the second matching circuit 4 side, and the final stage amplifier 2 becomes short-circuited (disconnected). Then, the second switch 101 is turned OFF to disable the feedback circuit 100C. The operation at this time is similar to the above-mentioned operation.

On the other hand, in the second output mode, similarly to the above (FIG. 3), the first switches 7 and 8 are switched so that the final stage amplifier 2 is connected in series to the negative feedback amplifier 10C, and the second switch 101 is turned ON to enable the feedback circuit 100C.

In this case, the signal that is negatively fed back to the input terminal 90 from the output terminal 91 of the driver amplifier 1 at low frequency is more likely to flow to the input terminal 20 side because the DC blocking capacitive element 104 is seen as high impedance.

Therefore, power of the negative feedback signal input to the driver amplifier 1 is decreased and the loop gain is decreased, and hence the oscillation of the driver amplifier 1 at low frequency can be suppressed.

As described above, the feedback circuit 100C according to the third embodiment (FIG. 7) of the present invention includes the DC blocking capacitive element 104 that is loaded on the input side of the driver amplifier 1, and the negative feedback amplifier 10C (feedback loop) is formed by including the DC blocking capacitive element 104. Thus, at low frequency, the DC blocking capacitive element 104 functions as high impedance.

In this way, power of the negative feedback signal input to the driver amplifier 1 is decreased and the loop gain is decreased, and hence the oscillation of the driver amplifier 1 at low frequency can be suppressed as compared to the above-mentioned first embodiment.

The DC blocking capacitive element 104 can be shared by a capacitive element that is usually loaded on the input side of the driver amplifier 1, and hence there is no extra cost increase.

### Embodiment 4

The above-mentioned first to third embodiments (FIGS. 1, 6, and 7) use the negative feedback amplifiers 10, 10B, and 10C that perform two kinds of gain switching operations in accordance with the first and second output modes. Alternatively, however, as illustrated in FIG. 8, a negative feedback amplifier 10D that performs any M kinds of gain switching operations may be used.

FIG. 8 is a circuit block diagram illustrating a configuration of a multiple power mode amplifier 200D according to a fourth embodiment of the present invention. The same components as described above (see FIG. 1) are denoted by the same reference symbols or suffixed with “D”, and detailed description thereof is omitted. In this embodiment, the application to the configuration of FIG. 1 is shown as a representative example, but it should be understood that the present invention is applicable also to the configuration of FIG. 6 or 7.

In FIG. 8, a feedback circuit 100D that is interposed in parallel between the input and output terminals 90 and 91 of the driver amplifier 1 is formed of M (M is a natural number of 2 or more) parallel loop circuits, and includes M second switches 101a, 101b, . . . , and 101m, M capacitive elements 102a, 102b, . . . , and 102m, and M resistive elements 103a, 103b, . . . , and 103m.

The multiple power mode amplifier 200D of FIG. 8 is different from the above-mentioned multiple power mode amplifier 200 (FIG. 1) in that M series-connected circuits formed of the M capacitive elements 102a to 102m and the M resistive elements 103a to 103m are loaded, and, in the second output mode, a control circuit 80D controls a required number of the M second switches 101a to 101m to be turned ON, to thereby adjust the feedback amount β of the feedback circuit 100D.

In this way, as compared to the above-mentioned first embodiment, M kinds of gains can be obtained, and hence fine adjustment of the gain can be performed. Thus, the multiple power mode amplifier can be applied also to a multi-mode system that requires a large number of output modes.

Next, description is given of the specific operation according to the fourth embodiment of the present invention illustrated in FIG. 8.

First, the operation in the first output mode is similar to the above-mentioned operation (FIG. 2) and is therefore omitted.

On the other hand, in the second output mode, the control circuit 80D controls the first switches 7 and 8 so that the final stage amplifier 2 is connected in series to the negative feedback amplifier 10D, and, in accordance with a required gain, selects ON/OFF of the second switches 101a to 101m to control a required number of the second switches 101a to 101m to be turned ON.

Specifically, only the second switch 101a is turned ON in the case of enabling only the capacitive element 102a and the resistive element 103a at the lowest stage. Only the second switches 101a and 101b are turned ON in the case of enabling only the capacitive elements 102a and 102b and the resistive elements 103a and 103b at the lowest and second lowest stages. All the M second switches 101a to 1 01m are turned ON in the case of enabling the capacitive elements 102a to 102m and the resistive elements 103a to 103m up to the top stage. In this way, the resistance value of the feedback circuit 100D is sequentially decreased, and the feedback amount β is increased while the gain is decreased. Thus, the gain of the negative feedback amplifier 10D can be adjusted in M ways.

As described above, according to the fourth embodiment (FIG. 8) of the present invention, the M series-connected circuits each formed of the capacitive element and the resistive element are loaded in parallel between the input and output terminals 90 and 91 of the driver amplifier 1 to constitute the feedback circuit 100D, and the feedback amount β of the feedback circuit 100D is adjusted by turning ON/OFF the M second switches 101a to 101m. Thus, M kinds of gains can be obtained, and the fine adjustment of the gain can be performed as compared to the above-mentioned first embodiment.

Specifically, the resistance value and the capacitance value of the feedback circuit 100D, which is formed of the M series-connected circuits (the capacitive elements 102a to 102m and the resistive elements 103a to 103m connected in series) connected in parallel via the second switches 101a to 101m, are variably set by turning ON/OFF the second switches 101a to 101m. Thus, both the feedback amount β corresponding to the resistance value and the frequency characteristics corresponding to the capacitance value can be variably set.

Further, the multiple power mode amplifier can be applied also to a multi-mode system that requires a larger number of output modes.

### Embodiment 5

According to the above-mentioned fourth embodiment (FIG. 8), in the second output mode, the M series-connected circuits each formed of the capacitive element and the resistive element are selectively enabled so that both the resistance value and the capacitance value (feedback amount β and frequency characteristics) of the feedback circuit 100D are variably set. Alternatively, however, any one of the capacitive element and the resistive element may be a fixed value, and only the other may be selectively switched.

For example, as illustrated in FIG. 9, a single capacitive element 102 is interposed between the second switch 101a and the output terminal 91 of the driver amplifier 1, and the M resistive elements 103a to 103m are connected in parallel via the second switches 101a to 101m, to thereby variably set only the resistance value of a feedback circuit 100E by turning ON/OFF the second switches 101a to 101m. In this way, only the feedback amount β (gain) can be arbitrarily set.

Alternatively, in place of the capacitive element 102 of FIG. 9, a single resistive element 103 is interposed between the second switch 101a and the output terminal 91 of the driver amplifier 1, and the M capacitive elements 102a to 102m (see FIG. 8) are connected in parallel via the second switches 101a to 101m, to thereby variably set only the capacitance value of the feedback circuit by turning ON/OFF the second switches 101a to 101m. In this way, only the capacitance value (frequency characteristics) of the feedback circuit 100E can be arbitrarily set.

### Embodiment 6

Although not specifically described in the above-mentioned first to fifth embodiments, a high-pass filter, a low-pass filter, or a phase lead circuit may be additionally interposed in the feedback circuit 100, 100B, 100C, or 100D.

For example, in the case where a high-pass filter is added to the feedback circuit 100 of the above-mentioned first embodiment (FIG. 1), as illustrated in FIG. 10, a capacitive element 105 forming a high-pass filter is additionally interposed in a feedback circuit 100F, and a resistive element 106 forming the high-pass filter is interposed between the feedback circuit 100F and the ground.

In this way, the feedback of a low frequency signal is blocked, and hence only the feedback amount of a high frequency signal can be enhanced and set.

On the other hand, in the case where a low-pass filter is added to the feedback circuit, in place of the capacitive element 105 of FIG. 10, a resistive element forming a low-pass filter is additionally interposed in a feedback circuit, and a capacitive element forming the low-pass filter is interposed between the feedback circuit and the ground.

In this way, the feedback of a high frequency signal is blocked, and hence only the feedback amount of a low frequency signal can be enhanced and set.

Alternatively, in the case where a phase lead circuit is added to the feedback circuit, as illustrated in FIG. 11, a parallel-connected circuit of a capacitive element 107 and a resistive element 108 forming a phase lead circuit is additionally interposed in a feedback circuit.

In this way, a phase delay of a feedback signal can be prevented to avoid oscillation.

### Embodiment 7

Although not specifically described in the above-mentioned first to sixth embodiments, a heterojunction bipolar transistor (HBT) may be used as the driver amplifier 1 and the final stage amplifier 2.

In this way, high-speed operation of the multiple power mode amplifier can be performed without impairing high efficiency characteristics over a wide range of output power, and hence the multiple power mode amplifier can be used for various applications.

In the above-mentioned first to sixth embodiments, the multiple power mode amplifier having two output modes (low output power mode and high output power mode) has been described. However, the number of the output modes is not limited to two, and the present invention is applicable also to a multiple power mode amplifier having any plurality of output modes.

In this case, for example, the driver amplifier 1 and the final stage amplifier 2 are formed of a plurality of parallel amplifiers having different gains, and a required amplifier is selected via a switch.

Further, in each of the above-mentioned embodiments, a representative application example has been described. However, the configurations of the embodiments may be used in any combination. In this case, it should be understood that the effects of the embodiments are obtained in an overlapped manner.

### REFERENCE SIGNS LIST

1 driver amplifier, 2 final stage amplifier, 7, 7B, 8 first switch (first switching means), 10, 10B to 10G negative feedback amplifier, 80A to 80G control circuit, 100, 100B to 100G feedback circuit, 101, 101a to 101m second switch (second switching means), 102, 102a to 102m capacitive element, 103, 103a to 103m resistive element, 104 DC blocking capacitive element, 105 capacitive element of high-pass filter, 106 resistive element of high-pass filter, 107 capacitive element of phase lead circuit, 108 resistive element of phase lead circuit, 200, 200B to 200G multiple power mode amplifier.

1. A multiple power mode amplifier having a plurality of output modes with different levels of output power, comprising:
N amplifiers, where N is a natural number of 2 or more, which are connected in series via switching means; and
a control circuit for controlling switching of a connection state and an ON/OFF state of the N amplifiers in accordance with the plurality of output modes,
wherein P amplifiers, where P is a natural number of 1 or more and P≦N, out of the N amplifiers constitute a driver amplifier, and constitute a negative feedback amplifier comprising a feedback circuit for negatively feeding back its own output signal to its own input side,
wherein N−P amplifiers out of the N amplifiers constitute a final stage amplifier that is connected in series to the negative feedback amplifier in a disconnectable manner, and
wherein the control circuit is configured to:
in a first output mode in which required output power is relatively low, disconnect the final stage amplifier from the negative feedback amplifier, and disable the feedback circuit connected in parallel to the driver amplifier; and
in a second output mode in which required output power is relatively high, connect the final stage amplifier in series to the negative feedback amplifier, and enable the feedback circuit.

2. The multiple power mode amplifier according to claim 1, further comprising:
first switching means that is provided to the final stage amplifier; and
second switching means that is provided to the feedback circuit,
wherein the control circuit is configured to:
in the first output mode, switch the first switching means to short-circuit the final stage amplifier, and turn OFF the second switching means to disable the feedback circuit; and
in the second output mode, switch the first switching means to connect the final stage amplifier in series to the negative feedback amplifier, and turn ON the second switching means to enable the feedback circuit,
wherein the negative feedback amplifier is configured to, in the second output mode, amplify an input signal by an amplification factor lower than an amplification factor in the first output mode, and
wherein the final stage amplifier is configured to further amplify an output signal from the negative feedback amplifier only in the second output mode.

3. The multiple power mode amplifier according to claim 2, wherein the first switching means comprises a first switch, and the second switching means comprises a second switch.

4. The multiple power mode amplifier according to claim 2, wherein the first switching means and the second switching means are single switching means to be used in common.

5. The multiple power mode amplifier according to claim 1, wherein the feedback circuit comprises at least one of a resistive element and a capacitive element.

6. The multiple power mode amplifier according to claim 5, wherein the feedback circuit comprises a series-connected circuit of a resistive element and a capacitive element.

7. The multiple power mode amplifier according to claim 1, wherein the feedback circuit comprises a DC blocking capacitive element that is connected in series to an input side of the driver amplifier.

8. The multiple power mode amplifier according to claim 1, wherein the feedback circuit comprises a high-pass filter.

9. The multiple power mode amplifier according to claim 8, wherein the high-pass filter comprises a capacitive element that is additionally interposed in the feedback circuit, and a resistive element that is interposed between the feedback circuit and a ground.

10. The multiple power mode amplifier according to claim 1, wherein the feedback circuit comprises a low-pass filter.

11. The multiple power mode amplifier according to claim 10, wherein the low-pass filter comprises a resistive element that is additionally interposed in the feedback circuit, and a capacitive element that is interposed between the feedback circuit and a ground.

12. The multiple power mode amplifier according to claim 1, wherein the feedback circuit comprises a phase lead circuit.

13. The multiple power mode amplifier according to claim 12, wherein the phase lead circuit comprises a parallel-connected circuit of a resistive element and a capacitive element that are additionally interposed in the feedback circuit.

14. The multiple power mode amplifier according to claim 2, wherein the feedback circuit comprises M resistive elements, where M is a natural number of 2 or more, which are connected in parallel via the second switching means, and a resistance value of the feedback circuit is variably set by turning ON/OFF the second switching means.

15. The multiple power mode amplifier according to claim 2, wherein the feedback circuit comprises M capacitive elements, where M is a natural number of 2 or more, which are connected in parallel via the second switching means, and a capacitance value of the feedback circuit is variably set by turning ON/OFF the second switching means.

16. The multiple power mode amplifier according to claim 2,
wherein the feedback circuit comprises M series-connected circuits, where M is a natural number of 2 or more, which are connected in parallel via the second switching means,
wherein the M series-connected circuits each comprise a capacitive element and a resistive element that are connected in series, and
wherein a resistance value and a capacitance value of the feedback circuit are variably set by turning ON/OFF the second switching means.

17. The multiple power mode amplifier according to claim 1, wherein the N amplifiers each comprise a heterojunction bipolar transistor.
